(19) United States
(12) Patent Application Publication
(10) Pub. No.: US 2026/0098910 A1
(43) Pub. Date: Apr. 9, 2026

(54) Method and System for Predicting SOHC for Electric Vehicle (EV)

(71) Applicant: LG Energy Solution, Ltd., Seoul (KR)

(72) Inventors: Min Young Kim, Daejeon (KR); Ji Hye Park, Daejeon (KR); Jee Soon Choi, Daejeon (KR)

(73) Assignee: LG Energy Solution, Ltd., Seoul (KR)

(21) Appl. No.: 19/114,565

(22) PCT Filed: Jan. 12, 2024
(86) PCT No.: PCT/KR2024/000589

§ 371 Date: Mar. 24, 2025

(30) Foreign Application Priority Data
May 30, 2023 (KR) 10-2023-0069253
Jan. 8, 2024 (KR) 10-2024-0002868

(51) Int. Cl. G01R 31/392; G01R 31/367; G06N 20/00

(52) U.S. Cl. CPC G01R 31/392; G01R 31/367; G06N 20/00

(57) ABSTRACT

Aspects of the disclosure provide a method and system for estimating a real-time SOHC by generating an SOHC estimation model using cell data and first field data acquired from a test battery and inputting second field data acquired from a battery in use into the SOHC estimation model, in estimating the SOHC of the battery in use.

### CROSS-REFERENCE TO RELATED APPLICATIONS

The present application is a national phase entry under 35 U.S.C. § 371 of International Patent Application No. PCT/KR2024/000589, filed Jan. 12, 2024, which claims priority from Korean Patent Application No. 10-2024-0002868, filed Jan. 8, 2024, and Korean Patent Application No. 10-2023-0069253, filed May 30, 2023, all of which are incorporated herein by reference.

### BACKGROUND

In estimating the state of health capacity (SOHC) of the battery for the electric vehicle (EV) using field data, a battery capacity value calculated from an on-board battery management system (BMS) was used. However, since the battery capacity value calculated in this way cannot be considered a true value, the SOHC value of the battery estimated using this value contains more errors.

Therefore, a method for calculating the SOHC directly from cell data is needed.

### BRIEF SUMMARY

Aspects of the disclosure provide a method and system for estimating an accurate SOHC of a field battery by generating an accurate SOHC estimation model using cell data acquired during a battery cell test process and using the SOHC estimation model.

Aspects of the disclosure provide an SOHC estimation model generation device including a battery test device that acquires cell data from a plurality of battery cells and first field data from other battery cells or from different charge/discharge cycles during a cell test process, and an SOHC estimation model generation unit that calculates a first SOHC value from the cell data, constructs a first training dataset with the cell data as an input value and the first SOHC value as a label value to generate a first SOHC estimation model that estimates an SOHC value from cell data, inputs the first field data into the first SOHC estimation model to calculate a second SOHC value, constructs a second training dataset with the first field data and the second SOHC value as a label value, and retrains the first SOHC estimation model with the second training dataset to generate a second SOHC estimation model.

Aspects of the disclosure provide an application BMS that includes an SOHC estimation model unit including an SOHC estimation model, and receives field data from a field battery operating in an application, inputs the field data into the SOHC estimation model, and calculates a real-time SOHC value of the field battery.

In some examples, the SOHC estimation model is generated by acquiring cell data from a plurality of battery cells and acquiring first field data from other battery cells or different charge/discharge cycles during a cell test process, calculating a first SOHC value from the cell data, constructing a first training dataset with the cell data and the first SOHC value as a label value to generate a first SOHC estimation model that estimates an SOHC value from cell data, inputting the first field data into the first SOHC estimation model to calculate a second SOHC value, constructing a second training dataset with the first field data and the second SOHC value as a label value, and retraining the first SOHC estimation model with the second training dataset to generate a second SOHC estimation model.

Aspects of the disclosure provide an SOHC estimation system for a field battery including a battery test device that acquires cell data from a plurality of battery cells and first field data from other battery cells or from different charge/discharge cycles during a cell test process, an SOHC estimation model generation unit that calculates a first SOHC value from the cell data, constructs a first training dataset with the cell data and the first SOHC value as a label value to generate a first SOHC estimation model that estimates an SOHC value from cell data, inputs the first field data into the first SOHC estimation model to calculate a second SOHC value, constructs a second training dataset with the first field data and the second SOHC value as a label value, and retrains the first SOHC estimation model with the second training dataset to generate a second SOHC estimation model, and an application BMS that includes an SOHC estimation model unit including the second SOHC estimation model as an SOHC estimation model, and receives field data from a field battery operating in an application, inputs the field data into the SOHC estimation model, and calculates a real-time SOHC value of the field battery.

Aspects of the disclosure provide an SOHC estimation method for a field battery cell including a cell data acquisition process of acquiring cell data from a plurality of battery cells during a cell test process, a first SOHC value calculation process of calculating a first SOHC value corresponding to the cell data, a first SOHC estimation model generation process of training and generating a first SOHC estimation model that estimates an SOHC value from cell data using the cell data as an input value and the first SOHC value as a first label value, a first field data acquisition process of acquiring second cell data different from the first field data from a plurality of battery cells during the cell test process, a second SOHC estimation value calculation process of generating a second SOHC estimation value corresponding to first field data by inputting the first field data into the generated first SOHC estimation model, a second SOHC estimation model generation process of generating a second SOHC estimation model by retraining the first SOHC estimation model using the generated second SOHC estimation value as a label value and the first field data as an input value, and an SOHC value estimation process of estimating an SOHC value during operation of predetermined battery cells by inputting field data generated while operating the predetermined battery cells into the second SOHC estimation model.

According to aspects of the disclosure, the first SOHC estimation model is generated using cell data obtained during the battery test process, and then the second SOHC estimation model is generated by retraining the first SOHC estimation model using the calculated SOHC value calculated by using the first SOHC estimation model as a label value and apply the second SOHC estimation model as the final SOHC estimation model, thereby providing a estimation model with increased accuracy using the on-board calculated capacity value.

### BRIEF DESCRIPTION OF THE DRAWINGS

The following drawings attached to this specification illustrate aspects of the disclosure along with the detailed description. Accordingly, the disclosure should not be construed as limited to only the matters described in such drawings.

FIG. 1 is a block diagram of an SOHC estimation system according to aspects of the disclosure.

FIG. 2 is a block diagram of an SOHC estimation system according to aspects of the disclosure.

FIG. 3 is a flowchart illustrating an SOHC estimation model generation procedure and an SOHC estimation method using the generated estimation model according to aspects of the disclosure.

### DETAILED DESCRIPTION

The technology provides for estimating a real-time SOHC by generating an SOHC estimation model using cell data acquired from a test battery and first field data different the cell data and inputting second field data acquired from a battery in use into the SOHC estimation model, in estimating the SOHC of the battery in use.

The terms used in the disclosure follow the definitions of the terms described below unless otherwise defined.

Aspects of the disclosure construct a model that estimates the SOHC of the battery in use from cell data and field data. In aspects of the disclosure, the state of health capacity (SOHC) means a ratio of capacity reduction due to degradation to an initial capacity of the battery. Generally, it is calculated as SOHC(%)=(current battery capacity/initial battery capacity)×100. Here, the current battery capacity represents an actual capacity of the battery that changes depending on use and charge-discharge cycles, and the initial battery capacity represents the capacity when the battery is first manufactured. It may be determined that the closer the SOHC value is to 100%, the better the health of the battery, and as the SOHC value decreases, the life of the battery is shortened and performance deteriorates.

In aspects of the disclosure, the cell data means battery cell data acquired from a test battery or reference battery during a cell test process. In aspects of the disclosure, the field data means battery data acquired from an in-use battery which is being used in an application such as a vehicle.

In aspects of the disclosure, a cloud battery management system (BMS) means a system in which the battery management function is executed on a cloud server and allows a user to monitor and manage a battery state in real time through a web browser anytime, anywhere. The cloud BMS can centrally and efficiently monitor and control a battery system in various locations, and can collect and analyze data and perform estimation analysis. In addition, the cloud BMS has the effect of optimizing overall energy management by sharing and linking data between multiple systems.

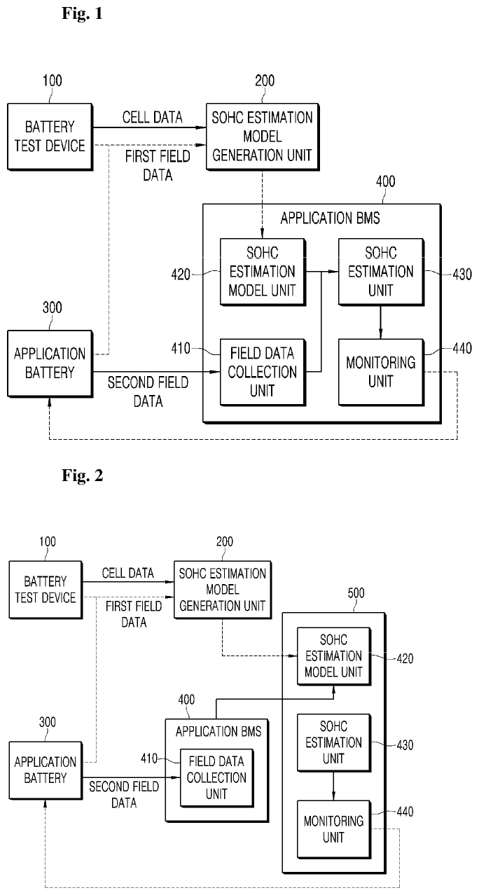

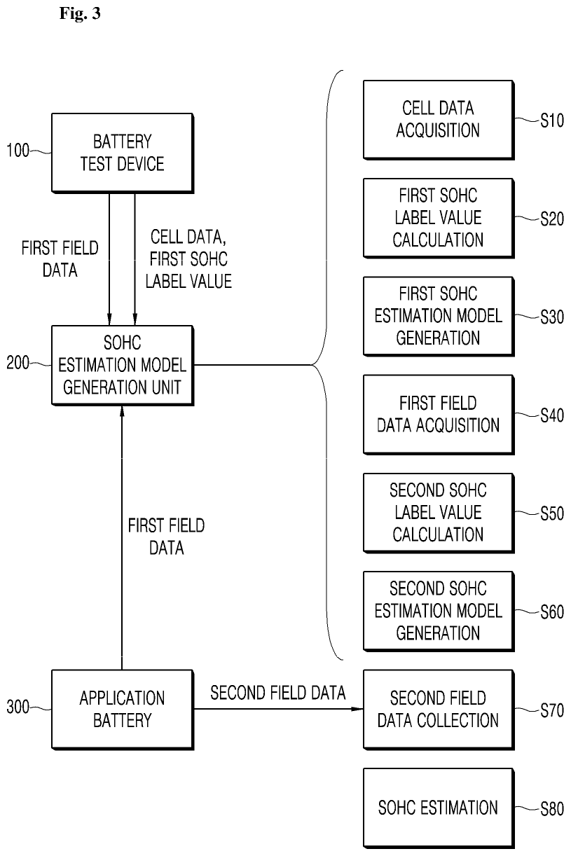

The SOHC estimation system for the field battery according to aspects of the disclosure is a system that performs a real-time SOHC estimation method for the field battery. The SOHC estimation system is described with reference to FIGS. 1 and 2.

As illustrated in FIG. 1, the system includes an SOHC estimation model generation unit 200 and an application BMS 400 that is installed with a generated estimation model, receives second field data from the field battery being used in the application, and calculates a real-time SOHC estimation value of the field battery from this, and the application BMS 400 may be configured as the cloud BMS. In addition, the SOHC estimation model generation unit 200 generates an SOHC estimation model from cell data received from a battery test device 100 and first field data received from an application battery 300.

As illustrated in FIG. 2, an SOHC estimation model unit 420 and an SOHC estimation unit 430 may be configured as a separate SOHC estimation device 500 instead of being mounted on the application BMS 400.

The battery test device 100 is a device that performs various tests on the battery after manufacturing the battery. Aspects of the disclosure use cell data including various state information of test batteries generated during a battery test from the known battery test device 100 as data for generating the SOHC estimation model.

The battery test device 100 acquires the cell data from test batteries and transmits the cell data to the SOHC estimation model generation unit 200.

The SOHC estimation model generation unit 200 is a configuration that generates an SOHC estimation model using not only the cell data described above but also first field data, and includes a computer algorithm that performs a corresponding process. Aspects of the disclosure use a known neural network as a neural network that is the basis of the SOHC estimation model, and is characterized by data and a training method for training the SOHC estimation model.

The SOHC estimation model generator 200 generates the SOHC estimation model by performing processes S10 to S60 described later, and provides the generated estimation model, that is, a computer-implemented algorithm for calculating an SOHC prediction value of the battery, to the SOHC estimation model unit 420 online or offline.

The SOHC estimation model generation unit 420 obtains the cell data and first SOHC data, which is an SOHC value corresponding to the cell data, as a first label value from the battery test device or a previously secured reference data set, constructs a first training dataset with the cell data and the first SOHC value, which is the first label value, and generates a first SOHC estimation model that estimates the SOHC value from the cell data. The first SOHC value is the SOHC value calculated based on the cell data from an on-board BMS of the test battery, a predetermined artificial neural network model configured to estimate the SOHC value from cell data may be used as the first SOHC estimation model, and a support vector regression (SVR) model is applied thereto in one example, and a first SOHC estimation model is obtained by performing machine learning that obtains a first parameter set including coefficients, intercepts, and model parameters that determine the regression function of the SVR model, by using the first training dataset with the cell data as input and the first SOHC value as a label value. The first training data set is {cell data, first SOHC}.

After that, the SOHC estimation model generation unit 420 acquires first field data from a predetermined field battery and inputs the first field data into the first SOHC estimation model to calculate a second SOHC value as a second label value, and constructs a second training dataset {first field data, second SOHC value} with the first field data as an input value and the second SOHC value as a label value. The second SOHC value is an SOHC value calculated by inputting the first field data into the first SOHC estimation model.

In aspects of the disclosure, first field data may be obtained from the battery test device 100. In this case, the battery test device 100 acquires cell data, which is obtained from a test battery other than the test battery from which the cell data was obtained, or from charge/discharge cycles different from those when the cell data was acquired, as first field data. In this case as well, the second training data set is set to {first field data, second SOHC value}.

After that, a second SOHC estimation model is generated by retraining the first SOHC estimation model with the second training dataset to obtain the second parameter set, and the second SOHC estimation model is provided as a final SOHC estimation model. The provided second SOHC estimation model is installed on the SOHC estimation model unit 420 of the application BMS 400, which will be described later.

The application BMS 400 is a battery management device that manages the application battery 300, and may be configured to include a field data collection unit 410, the SOHC estimation model unit 420, the SOHC estimation unit 430, and a monitoring unit 440, in addition to typical BMS components.

The application BMS 400 collects field data such as battery state information from the application battery 300 in operation, and may be configured as an on-site battery management system (on-Site BMS) configured in the same location or facility as the application battery, or may be configured as the cloud BMS.

When the application BMS 400 is configured as the cloud BMS, the application BMS 400 is connected to a plurality of on-board BMSs through a predetermined wired/wireless communication network and receives the cell data and field data from the on-board BMSs.

In aspects of the disclosure, the on-board BMS means the BMS of the application battery 300 or the test battery from which the first SOHC value is calculated, and the on-Site BMS means that the application BMS 400, which receives field data from the on-board BMSs of a plurality of application batteries 300, is physically the same as or adjacent to the application battery 300, to form one system. When the application BMS 400 is separated from the application battery 300 and configured to receive the field data through a wired/wireless network, it is referred to as the cloud BMS.

Such an application BMS 400 includes the following configurations in addition to a data path connected to a plurality of application batteries 300 or a communication device (not illustrated) connected to a wired/wireless network.

The field data collection unit 410 collects field data from the battery used in the application and transmits the field data to the SOHC estimation unit 430. The field data collected by the field data collection unit 410 is indicated as second field data in FIGS. 1 and 2 in order to distinguish the field data from first field data for retraining the SOHC estimation model.

The SOHC estimation model unit 420 is configured with a memory device installed with the SOHC estimation model generated according to an SOHC estimation model generation method according to aspects of the disclosure, which will be described later. The SOHC estimation model is a computer-implemented algorithm that constructs an artificial neural network model which receives field data in real time and is trained to calculate a real-time SOHC estimation value of the application battery 300 corresponding to the real-time field data.

The SOHC estimation unit 430 reads the computer-implemented algorithm constructing the SOHC estimation model, inputs the field data into the SOHC estimation model, and outputs an SOHC estimation value corresponding to the field data. It may be configured with a processor of a computer device or an arithmetic device including a predetermined processor.

The monitoring unit 440 monitors the state of the application battery 300 based on the real-time SOHC estimation value calculated by the SOHC estimation unit 430.

As described above, the application BMS 400 may be mounted on an application device such as a vehicle, or may be configured as the cloud battery management system BMS. When it is configured as the cloud BMS, the cloud BMS may include a communication module that receives the field data from a remote location from the application battery 300.

Meanwhile, as illustrated in FIG. 2, the SOHC estimation system may be configured as a separate SOHC estimation device 500 without configuring the SOHC estimation model unit 420, SOHC estimation unit 430, and monitoring unit 440 within the application BMS 400.

Aspects of the disclosure estimate and calculate the SOHC of the cell in use through the following procedure.

The cell data acquisition process (S10) is a process of acquiring cell data from a plurality of battery cells during a cell testing process after cell manufacturing. The cell data may include at least one of a cumulative charge capacity during a charge cycle, a cumulative discharge capacity during a discharge cycle, cumulative charge energy, which is energy required for charging during the charge cycle, cumulative discharge energy, which is discharge energy during the discharge cycle, and an average temperature data of the battery cell, of the battery cell.

In some examples, the cell data may be limited to cell data obtained in a standard charge section, which has similar characteristics to field data and is a relatively standardized section. For standard charging, the charging speed can be set to 0.33 C-rate. The reason for limiting cell data to data obtained in the standard charge section is to secure cell data obtained in a test environment in a section similar to field data, which is data in an actual use environment.

In some examples, the cell data may be limited to cell data obtained in a predetermined partial charge section. In this case, the partial charge section may be a section of 3.6 to 3.9 V. The reason for limiting cell data to a predetermined partial charge section is to extract a common voltage section and extract a voltage section that has a high correlation with SOHC, during the battery test process, because there is a difference in charging start voltage for each cell in each cycle.

The first SOHC label value calculation process (S20) is a process of calculating the cell SOHC value corresponding to the cell data during the cell test process after cell manufacturing.

The first SOHC value calculated by the BMS during the test process after manufacturing the cell is the value calculated by the on-board BMS. The BMS at this time may be the on-board BMS used in the cell test process. As the method of calculating the first SOHC using cell data in the on-board BMS, a known method is used.

The first SOHC estimation model that estimates the SOHC value from the cell data is generated (S30) using the acquired cell data as input data and the first SOHC value corresponding thereto as a label value. The first SOHC estimation model is generated by performing machine learning on a known neural network-based model using the cell data and a first SOHC label value corresponding thereto.

First field data is acquired (S40) from the application battery 300 operating in an actual application, different from the test battery from which the cell data is acquired during the cell test process. Like cell data, the first field data is also composed of data including at least one of a cumulative charge capacity during a charge cycle, a cumulative discharge capacity during a discharge cycle, cumulative charge energy, which is energy required for charging during the charge cycle, cumulative discharge energy, which is discharge energy during the discharge cycle, and an average temperature data of the battery cell, of the battery cell, but is different in that the first field data is battery data obtained from a battery in operation in an actual application.

The first field data may be data acquired from a battery different from the battery for acquiring the second field data, which will be described later, or may be data acquired in cycles different from the charge/discharge cycles for acquiring the second field data.

The second SOHC label value calculation process (S50) is a process of inputting the first field data into the first SOHC estimation model to calculate the second SOHC label values corresponding to the first field data.

The second SOHC estimation model generation process (S60) is the process of generating the second SOHC estimation model by retraining the first SOHC estimation model. The process of generating the second SOHC estimation model is a process of generating the second SOHC estimation model by retraining the first SOHC estimation model with {first field data, second SOHC calculated value}, which is obtained by using the first field data as input data to the first SOHC estimation model and the second SOHC calculated value calculated from the first SOCH estimation model as a label value, as training data.

The second field data collection process (S70) is the process of collecting second field data from the field battery in operation in an application for which it is intended to estimate the SOHC. Like cell data, the second field data also includes at least one of a cumulative charge capacity during a charge cycle of the battery cell, a cumulative discharge capacity during a discharge cycle, cumulative charge energy, which is energy required for charging during the charge cycle, cumulative discharge energy, which is discharge energy during the discharge cycle, and an average temperature data of the battery cell.

The SOHC estimation process for the field battery (S80) is the process of calculating the real-time SOHC value of the field battery (application battery) by inputting the collected field data (second field data) into the second SOHC estimation model.

As described above, aspects of the disclosure have been described with reference to the accompanying drawings. A person skilled in the art to which the disclosure pertains will understand that aspects of the disclosure may be practiced in forms different from the disclosed examples without changing the technical idea or essential features of the disclosure. Aspects of the disclosure are illustrative and should not be construed as limiting.

1-12. (canceled)

13. A state of health capacity (SOHC) estimation model generation device comprising:
a battery test device configured to acquire cell data from a plurality of battery cells during a cell test process; and
an SOHC estimation model generation unit configured to:
calculate a first SOHC value from the cell data;
construct a first training dataset with the cell data as an input value and the first SOHC value as a label value;
generate a first SOHC estimation model by training a machine learning model using the cell data and the first SOHC value as first training data; and
generate a second SOHC estimation model by retraining the first SOHC estimation model using first field data and a second SOHC value as second training data, wherein:
the first field data is battery data acquired from an application battery in operation, other cell data acquired from battery cells other than the plurality of battery cells from which the cell data was acquired, or the cell data acquired from the plurality of battery cells in different charge/discharge cycles; and
the second SOHC value is a value calculated by inputting the first field data into the first SOHC estimation model.

14. An application battery management system (BMS) comprising a SOHC estimation model unit comprising the second SOHC estimation model of claim 13.

15. The application BMS of claim 14, wherein the application BMS is configured to:
receive field data from an application battery in operation in an application;
input the field data into the second SOHC estimation model; and
calculate a real-time SOHC value of the application battery.

16. The application BMS of claim 14, wherein the cell data is obtained from the plurality of cells of a test battery.

17. The application BMS of claim 14, further comprising:
a field data collection unit that receives the first field data and second field data from the application battery through a communication network.

18. The application BMS of claim 17, wherein the second SOHC estimation model receives the second field data from the application battery.

19. The application BMS of claim 14, wherein the cell data comprises at least one of cumulative charge capacity, cumulative discharge capacity, cumulative charge energy, cumulative discharge energy, or average temperature data of the plurality of battery cells.

20. The application BMS of claim 14, wherein the first field data is obtained in a standard charge section and a predetermined partial charge section.

21. The application BMS of claim 14, wherein the second SOHC estimation model is a regression model or a neural network model.

22. An SOHC estimation system for an application battery comprising:
a battery test device configured to acquire cell data from a plurality of battery cells during a cell test process; and
an application BMS configured to receive field data from an application battery in operation in an application, input the field data into an SOHC estimation model, and calculate a real-time SOHC value of the application battery, wherein the application BMS comprises:
an SOHC estimation model generation unit configured to:
calculate a first SOHC value from the cell data;
construct a first training dataset with the cell data as an input value and the first SOHC value as a label value;
generate a first SOHC estimation model by training a machine learning model using the cell data and the first SOHC value as first training data; and
generate a second SOHC estimation model by retraining the first SOHC estimation model using first field data and a second SOHC value as second training data, wherein the second SOHC value is a value calculated by inputting the first field data into the first SOHC estimation model; and
an SOHC estimation model unit that comprises the second SOHC estimation model.

23. The SOHC estimation system of claim 22, wherein the cell data is obtained from the plurality of cells of a test battery.

24. The SOHC estimation system of claim 22, wherein the application BMS further comprises a field data collection unit that receives the first field data and second field data from the application battery through a communication network.

25. The SOHC estimation system of claim 24, wherein the second SOHC estimation model receives the second field data form the application battery.

26. The SOHC estimation system of claim 22, wherein the cell data comprises at least one of cumulative charge capacity, cumulative discharge capacity, cumulative charge energy, cumulative discharge energy, or average temperature data of the plurality of battery cells.

27. The SOHC estimation system of claim 22, wherein the first field data is data obtained in a standard charge section and a predetermined partial charge section.

28. The SOHC estimation system of claim 22, wherein the second SOHC estimation model is a regression model or a neural network model.

29. An SOHC estimation method for a field battery cell, comprising:
acquiring first cell data from a plurality of battery cells during a cell test process;
calculating a first SOHC value from the first cell data;
constructing a first training dataset with the first cell data as an input value and the first SOHC value as a label value;
generating a first SOHC estimation model by training a machine learning model using the first cell data and the first SOHC value as first training data;
generating a second SOHC estimation model by retraining the first SOHC estimation model using first field data and a second SOHC value as second training data, wherein the second SOHC value is a value calculated by inputting the first field data into the first SOHC estimation model; and
estimating an SOHC value during operation of the plurality of battery cells by inputting field data generated while operating the plurality of battery cells into the second SOHC estimation model.

30. The SOHC estimation method of claim 29, wherein the cell data comprises at least one of cumulative charge capacity, cumulative discharge capacity, cumulative charge energy, cumulative discharge energy, and average temperature data of the plurality of battery cells.

31. The SOHC estimation method of claim 29, wherein the first field data is data obtained in a standard charge section and a predetermined partial charge section.

32. The SOHC estimation method of claim 29, wherein the second SOHC estimation model is a regression model or a neural network model.
